(19) United States
(12) Patent Application Publication
(10) Pub. No.: US 2026/0031312 A1
(43) Pub. Date: Jan. 29, 2026

(54) Beam Plasma Source Enhanced Magnetron Sputtering

(71) Applicant: Board of Trustees of Michigan State University, East Lansing, MI (US)

(72) Inventors: Qi Hua FAN, Okemos, MI (US); Ethan NEITZKE, East Lansing, MI (US)

(73) Assignee: Board of Trustees of Michigan State University, East Lansing, MI (US)

(21) Appl. No.: 19/280,174

(22) Filed: Jul. 25, 2025

Related U.S. Application Data
(60) Provisional application No. 63/676,471, filed on Jul. 29, 2024.

(51) Int. Cl. H01J 37/34; C23C 14/35

(52) U.S. Cl. CPC H01J 37/3408; C23C 14/35; H01J 37/3426; H01J 37/3452; H01J 37/3461; H01J 2237/3326

(57) ABSTRACT

Beam plasma source enhanced magnetron sputtering, is provided. An aspect of the present apparatus and method of use employs a magnetron apparatus including: a vacuum chamber; reactive gas; a workpiece substrate; and a magnetron which includes spaced apart magnetron magnets and a sputter target located adjacent to the magnets with a primary axis of the magnetron being offset from a nominal plane of the workpiece substrate by 20-70°; and an ion source which includes an anode, a cathode, and ion source magnets. In one configuration, an ion emission centerline of an ion source is substantially perpendicular to a nominal facing surface or plane of a workpiece substrate, and in a second configuration, the ion emission centerline is offset angled by 20-80° from the nominal surface or plane of the substrate. In another aspect of the present magnetron apparatus and method, a sputter target has an axis with an offset angle 35-50° relative to a workpiece substrate surface, and an ion source has an ion emission centerline substantially perpendicular to the workpiece substrate surface.

### CROSS-REFERENCE TO RELATED APPLICATION

The present application claims priority to U.S. provisional patent application Ser. No. 63/676,471, filed on Jul. 29, 2024, which is incorporated by reference herein.

### GOVERNMENT RIGHTS

This invention was made with government support under 2243110 awarded by the National Science Foundation. The government has certain rights in the invention.

### BACKGROUND AND SUMMARY

The present application generally pertains to magnetron sputtering and more particularly to a method for making thin films using beam plasma source enhanced magnetron sputtering.

Ion sources are widely used for surface engineering and thin film deposition. Energetic ions created from an ion source can enhance surface reactions, sputter a target, and modulate surface roughness. Hence, ion sources have been an important tool in manufacturing semiconductor integrated circuits, flat panel displays and functional coatings. Recently advances in ion sources are disclosed in commonly owned U.S. Patent Publication No. 2022/0013324 entitled “Single Beam Plasma Source” which published to Fan on Jan. 13, 2022, and U.S. Pat. No. 11,049,697 entitled “Single Beam Plasma Source” which issued to Fan, et al. on Jun. 29, 2021, both of which are incorporated by reference herein.

Furthermore, magnetron sputtering is a common technology used to make thin films in research laboratories and industry. The thin films produced by traditional magnetron sputtering generally have a porous microstructure at the atomic scale, as is shown in FIG. 1, which includes pronounced defects that result in poor electrical conductivity and optical transmittance. These conventional magnetron processes generally result in loosely packed atoms 21 on a workpiece substrate 23 due to their limited kinetic energies.

Traditional magnetrons have a sputtering material source 25 mounted with an emission centerline 27 perpendicular to a plane 29 of the substrate and also deposit the thin films at high temperatures, such as 300° C., to enable the formation of polycrystalline structures. Disadvantageously, high-temperature processes not only require intensive energy but also expensive equipment.

Other exemplary magnetron configurations are disclosed in U.S. Patent Publication No. 2007/0209927 entitled “Magnetron Sputtering Device in Which Two Modes of Magnetic Flux Distribution (Balanced Mode/Unbalanced Mode Can be Switched from One to the Other . . . ” which published to Kamei, et al. on Sep. 13, 2007, and U.S. Pat. No. 10,741,649 entitled “High Mobility Doped Metal Oxide Thin Films and Reactive Physical Vapor Deposition Methods of Fabricating the Same” which issued to Sachet, et al. on Aug. 11, 2020, both of which are incorporated by reference herein. It is noteworthy, however, that neither of these conventional magnetrons employ both an offset angled ion source and an offset angled sputtering target material source, relative to a line perpendicular to a workpiece substrate. Additionally, these traditional magnetrons do not operate at or near room temperature which limits their use on certain workpiece substrates. More specifically, the Kamei dual magnetron device recognizes the problems associated with prior high temperature sputtering, but even its relatively lower temperature configuration still requires substrate heating to 300° C. during film formation, with an additional heating treatment of 500° C.

In accordance with the present invention, beam plasma source enhanced magnetron sputtering, is provided. An aspect of the present apparatus and method of use employs a magnetron apparatus including: a vacuum chamber; reactive gas; a workpiece substrate; and a magnetron which includes spaced apart magnetron magnets and a sputter target located adjacent to the magnets with a primary axis of the magnetron being offset from a nominal plane of the workpiece substrate by 20-70°; and an ion source which includes an anode, a cathode, and ion source magnets. In one configuration, an ion emission centerline of an ion source is substantially perpendicular to a nominal facing surface or plane of a workpiece substrate, and in a second configuration, the ion emission centerline is offset angled by 20-80° from the nominal surface or plane of the substrate. In another aspect of the present magnetron apparatus and method, a sputter target has an axis with an offset angle 35-50° relative to a workpiece substrate surface, and an ion source has an ion emission centerline substantially perpendicular to the workpiece substrate surface.

In yet another aspect of the present magnetron apparatus and method, a sputter target has an axis offset angled from a line perpendicular to a facing workpiece surface, wherein a temperature of a workpiece substrate is <150° C. during the ion emission and sputtering of the sputter target, and the layer has a polycrystalline thin film structure. Another aspect provides a holder supporting and moving a workpiece substrate during ion emission and sputtering of a sputter target, the holder cooling the workpiece substrate between room temperature and 150° C. during the ion emission and the sputtering of the sputter target, and an axis of the sputter target being offset angled relative to the workpiece substrate.

The present thin film deposition is advantageous over traditional devices. For example, the present apparatus and method are well suited for use at low temperature operation which allows for sputter growing a layer on a polymeric workpiece substrate. Furthermore, the low temperatures possible with some configurations of the present system allow for use of less expensive and less complicated equipment, such as avoiding some conventional cooling devices for the substrate and conventional high temperate materials for the equipment.

The offset angles of the sputtering target and, optionally, the ion source, relative to the upper surface of the substrate, result in beneficially more densely packing of sputter material atoms during layer growth on the substrate, as compared to traditional sputtering targets which are perpendicular to the substrate. Some thin films deposited by the present offset angles exhibit advantageously high electrical conductivity and enhanced optical properties such as transparency due to improved crystallinity. The dense packing of atoms achieved with the present offset angles, beneficially obtains a smoother outer surface of the layer. Additional features and benefits will become apparent from the following description and appended claims taken in conjunction with the accompanying drawings.

### BRIEF DESCRIPTION OF THE DRAWINGS

FIG. 1 is a diagrammatic cross-sectional view showing a prior art magnetron sputtering that produces loosely coating atoms on a workpiece;

FIG. 2 is a diagrammatic cross-sectional view showing the present magnetron apparatus;

FIG. 3 is a cross-sectional view showing a first embodiment of the present magnetron apparatus;

FIG. 4 is a side view photograph showing the first embodiment of the present magnetron apparatus, with a magnetron offset angled;

FIG. 5 is an X-ray diffraction pattern graph of p-type ZnTe thin films prepared at different magnetron incident angles, for the first embodiment of present magnetron apparatus;

FIG. 6 is a side view photograph showing the first embodiment of the present magnetron apparatus, with both the magnetron and an ion source offset angled;

FIG. 7 is an X-ray diffraction pattern graph of ITO thin films prepared at different ion source excitation voltages, for the first embodiment of present magnetron apparatus; and

FIG. 8 is a cross-sectional view showing a second embodiment of the present magnetron apparatus.

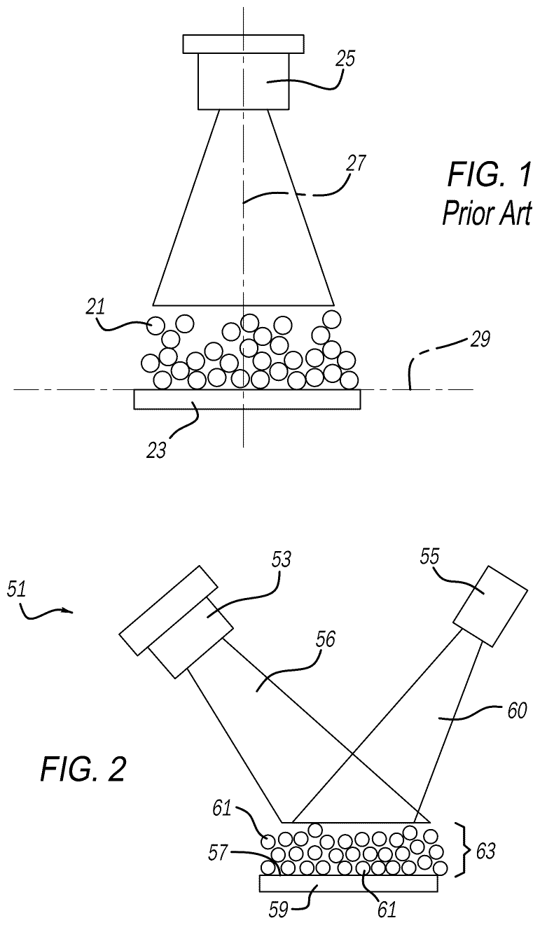

### DETAILED DESCRIPTION

The present magnetron apparatus 51 is generally illustrated in FIG. 2. Magnetron apparatus 51 includes a magnetron sputtering target 53 and an ion source 55. Target material atoms are ejected from magnetron sputtering target 53 generally along a sputter path 56 aimed at a nominal upper surface 57 of a workpiece substrate 59 which faces the target. Furthermore, an ion beam 60 is also aimed at nominal upper surface 57 of workpiece substrate 59. The orientations of magnetron sputtering target 53 and ion source 55 are offset angled from surface 57 of substrate 59, and their respective ejection path 56 and beam 60. The orientations of magnetron sputtering target 53 and ion source 55 are also offset angled from each other. These offset angles together cause more densely packing of atoms 61, sputtered from magnetron sputtering target 53, which create a generally smooth thin film layer 63 on surface 57 of the workpiece substrate.

The offset nature of magnetron sputtering target 53 and ion source 55, in addition to the presently preferred ion source excitation voltages, advantageously achieves low electrical resistivity and improved optical transparency of sputtered layer 63, which is ideally suited for use in making photovoltaic cells, screens for televisions or computers, and the like. The present magnetron apparatus and method are suitable for making thin films with tunable microstructures and properties, at low temperatures. Exemplary applications of sputtered layer 63 include, but are not limited to, semiconductor thin films, transparent conductive oxide thin films, metal thin films and superconductor thin films. It is desired that these thin film layers 63 form polycrystalline microstructure with low defect density, at low temperatures, and at practically high manufacturing cycle time speeds and sputter coating rates.

The present beam plasma source apparatus 51 can effectively dissociate the process gases and simultaneously emit an ion beam to densify the growing film layer 63. The ions transfer intensive kinetic energy to surface atoms 61, resulting in the formation of crystalline structures, optionally without the need for external heating, which beneficially reduces the manufacturing cost of thin film products.

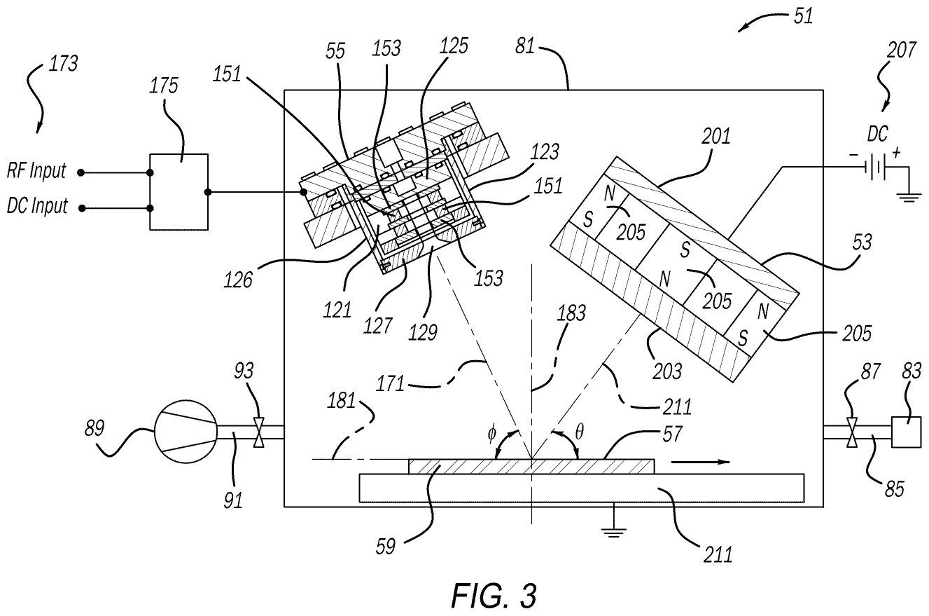

More specifically, a first embodiment of magnetron apparatus 51 is shown in FIGS. 3, 4 and 6. Magnetron 53, ion source 55 and workpiece substrate 59 are all located within a vacuum chamber 81, coupled to a gas supply 83 via a gas conduit 85 and valve 87, and coupled to a vacuum pump 89 via a vacuum conduit 91 and valve 93.

The preferred ion source 25 includes an anode 121 and a cathode 123. The anode is mounted upon an insulator 125. In an exemplary configuration, cathode 123 is set at an electrical ground potential. Cathode 123 can be a single piece or two pieces that include an external structural body 126 and an end cap 127 removably fastened thereto. Cap 127 of cathode 123 inwardly overhangs anode 121 with a single through-opening 129 in a center thereof defining an ion emission outlet. In the presently illustrated embodiment, the structural body and cap of cathode 123 have circular peripheries and opening 129 is circular. Body 126 and cap 127 of cathode 123 may be either a magnetic steel or non-magnetic metal. It is alternately envisioned that other arcuate shapes such as ovals or other single apertured, elongated hole shapes may be employed for these noted components.

Ion source 55 further includes multiple permanent magnets 151, preferably two, and multiple magnetic shunts 153, preferably three, are enclosed in anode 121. An open plasma region or area is internally located between the magnets and shunts, essentially aligned with opening 129. Magnets 151 and shunts 153 each have coaxially aligned, circular internal edges and circular external edges wherein they are each ring-shaped with a hollow center. Magnets 151 are sandwiched or stacked between shunts 153 such that the magnets are spaced apart from each other by the middle shunt. The upper and lower magnets are placed in series, e.g. N-S/N-S or S-N/S-N. Moreover, the cross-section of each side of the magnet and shunt assembly has a generally E-shape with the elongated and internal edges of shunts 153 extending toward a centerline axis 171 of ion source 55. It is noteworthy that all of the anode, including the magnets and shunts, are spaced internally away from all of cathode either by a gap or insulator.

A preferred electrical arrangement for the present single beam plasma or ion source apparatus 55, employ a power supply 173 having a direct current (“DC”) electrical circuit and radio frequency (“RF”) electrical circuit, which are electrically connected to anode 121 via an electronic DC/RF filter 175. When RF power is applied, DC voltage can be varied over a wide ranges including 0 V, wherein the RF power sustains the ion source at 0 V. Furthermore, the present ion source advantageously allows ion creation and emission independent of the operating gas since no filament is used; thus, argon, oxygen and other inert and reactive gases may be used. Moreover, the narrow focused ion beam advantageously provides a stable discharge without arcing.

Planar magnetron 53 includes a substantially flat base cathode plate 201 and a substantially flat sputter target 203, between which are sandwiched, multiple laterally spaced apart magnets 205. More particularly, there are preferably three magnets 205 with a central one of the magnets have a S-N polarity reversed from a N-S polarity of the outboard magnets, or vice versa. A DC power supply 207 is connected to base cathode plate 201. Sputter target 203 may have a generally annular ring-like true view shape or a generally rectangular true view shape. A primary axis 211 is aligned with the central magnet 205 and perpendicular to the flat front face of sputter target 203.

In a continuous production process, holder 211 supports and moves substrate workpiece 59 through vacuum chamber 81. Holder 211 may be a motor-driven conveyor or motor-driven rollers. Moreover, the holder acts as an anode such that the sputter material 61 generally moves along path 56 (see FIG. 2) and primary axis 171 thereof, toward substrate 59 on holder 211. In an exemplary configuration, substrate workpiece 59 is glass. In another exemplary configuration, the substrate workpiece is a rigid or flexible polymeric sheet.

In an exemplary configuration shown in FIGS. 3 and 5, a front face of sputter target 203 of the planar magnetron is set at an incident angle θ relative to a nominal plane 181 at an upper surface 57 of substrate 59, where θ is an offset angle between the normal direction or primary axis 211 of the magnetron target surface and the substrate surface. Similarly, ion source 55 is set at an incident angle ϕ offset relative to nominal surface plane 181 of substrate 181. The angle θ is in the range of 20-70°, preferably 35-50°. The angle ϕ is in the range of 20-90°, preferably 60-90°. For this configuration, angles ϕ and θ are each illustrated at approximately 45° (+/−2°). Primary axis 171 of magnetron 55 and centerline 211 of ion source are also offset from each other, on opposite sides of a line 183 which is perpendicular to plane 181, such as 40-85° of an offset angle between axis 171 and centerline 211.

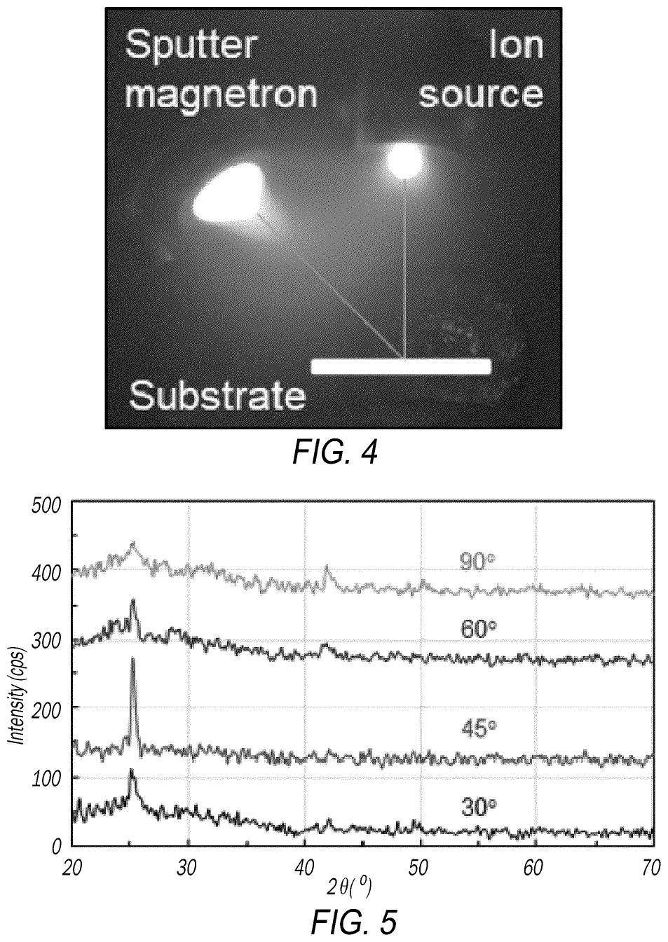

FIG. 4 illustrates an exemplary configuration wherein ion source enhanced planar magnetron sputtering is employed for depositing semiconductor p-type ZnTe thin films in Ar and N₂ mixture gases. In this example, the angles are θ=45° and ϕ=90° (+/−2°) for the magnetron and ion source, respectively. In other words, the primary axis of the magnetron sputter target is offset angled from perpendicular line 183 (see FIG. 3), while the ion emission centerline for the ion source is substantially coaxial with the perpendicular line. The orientation of the present configuration provides very different and improved performance as compared to the primary axis of the magnetron sputter target being aligned with the perpendicular line (i.e., the flat face of the target being parallel to the upper facing surface of the substrate).

Table 1 summarizes the p-type ZnTe thin film resistivity deposited with different angle θ values. The optimum magnetron incident angle is ˜45°, which results in the lowest resistivity. This optimum magnetron incident angle of 45° holds for the ion source excitation voltage of any values between 0 to 300 V, while the lowest resistivity of ˜0.2 Ohm-cm can be achieved with an ion source voltage of ˜200 V and an optimum N₂/Ar flow ratio of 0.5-1%. Similar materials can include, but are not limited to: silicon carbides, aluminum nitride, and silicon nitride.

TABLE 1
Resistivity of p-type ZnTe thin films deposited by magnetron
sputtering, in which the magnetron incident angle is
varied from 30-90°. 5% N2. 0 V ion source.

| Magnetron Incident | Film Thickness | Resistivity |
|---|---|---|
| Angle (°) | (nm) | (Ohm − cm) |
| 30 | 100 | 4.0 |
| 45 | 100 | 2.9 |
| 60 | 100 | 9.0 |
| 90 | 100 | 22.0 |

There is an optimum ion energy, depending on the thin film material and desired microstructure. The ion energy is determined by the excitation voltage. Accordingly, the ion source voltage range is preferably 0-400 V with an ion energy of 0-200 eV, while a more preferred ion source voltage range is 0-250 V with an ion energy of 0-120 eV.

Before the film deposition, the vacuum chamber is evacuated using the vacuum pumps. Then, source gases are introduced into the chamber through mass flow controllers to establish a processing pressure, preferably in the range of 1-10 mTorr. The beam plasma source is excited by one of the following powers: radio frequency (RF), direct current (DC), pulse DC, or a mixture of DC+RF. Furthermore, the coating thickness can be controlled by the processing time.

The low resistivity achieved at the optimum magnetron incident angle, ion source voltage, and process gas ratio is closely related to the microstructure of the p-type ZnTe thin films. For example, FIG. 5 shows X-ray diffraction patterns of a few p-type ZnTe thin films deposited with different magnetron incident angles, indicating that the film deposited at 45° sputtering magnetron incident angle possesses the best crystallization with preferential orientation. This graph demonstrates the notable performance differences based on different offset angles of magnetron 53 (see FIG. 3).

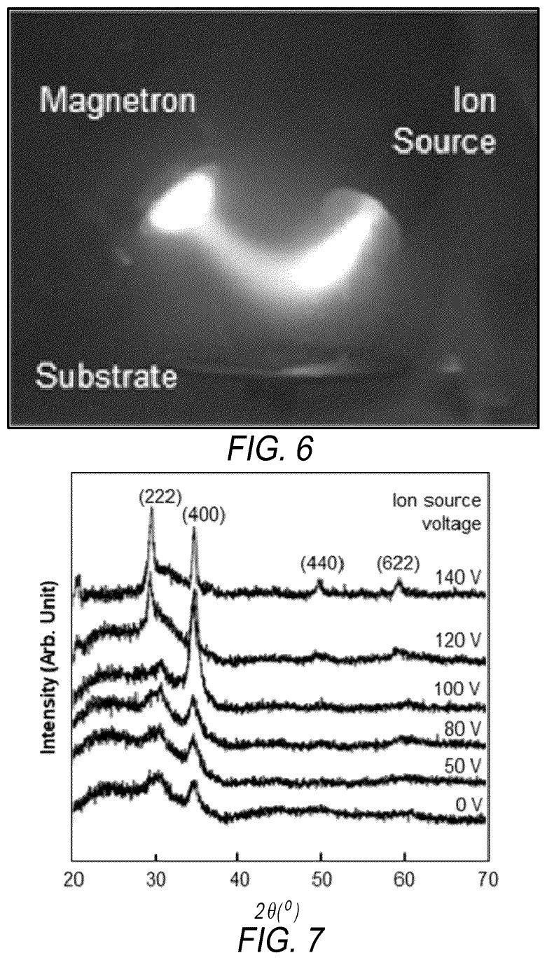

FIG. 6 illustrates ion source enhanced planar magnetron sputtering for depositing indium tin oxide (ITO) thin films. ITO is a transparent conductive oxide used in solar cells, displays and glass coatings. In this exemplary configuration, the angles are θ=45° and ϕ=45° for the magnetron 53 (see FIG. 3) and ion source 55, respectively. The process gases are Ar and O₂.

Turning now to FIG. 7, X-ray diffraction patterns of deposited ITO thin films with different ion source excitation voltages, can be observed. The optimum ion excitation voltage is about 100 V as evidenced by a single intensive (400) peak, implying strong preferential orientation of the crystals, which results in a smooth film and low resistivity. Similar materials include but are not limited to tin oxide based thin films, zinc oxide based thin films and cadmium oxide based thin films. This graph demonstrates the notable performance differences based on different ion source voltage values.

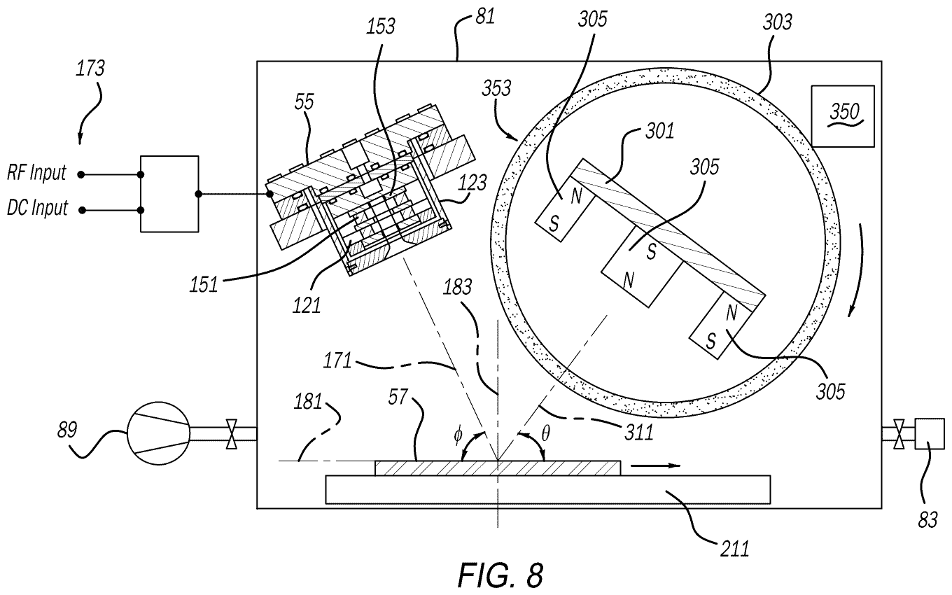

A second embodiment of a magnetron apparatus and method can be observed in FIG. 8. Vacuum chamber 81, ion source 55, workpiece substrate 57 and moving holder 211 are similar to that of the first embodiment. However, a rotary sputtering magnetron 353 is employed in this embodiment.

The present rotary magnetron 353 uses a tube-shaped, cylindrical sputtering target 303. Permanent magnets 305 are mounted on a steel shunt 301, which are located internal to sputtering target 303. An electric motor actuator 350 is coupled to sputtering target 303 for rotating it around magnets 305, which are stationary.

Rotary magnetron 353 is set at an incident angle θ relative to the substrate's surface plane, where θ is the angle between the normal primary axis 311 of the magnetron's magnet assembly and the nominal facing substrate surface or plane 181. On the other hand, emission centerline 171 of ion source 55 is set at an incident angle ϕ relative to substrate's surface plane 181. The angle θ is in the range of 20-70°, preferably 35-50°, and most preferably substantially 45° (+/−2°). The angle ϕ is in the range of 20-90°, preferably 60-90°.

There is an optimum ion energy, depending on the thin film material and desired microstructure. The ion energy is determined by the excitation voltage. The ion source voltage range is 0-400 V with an ion energy of 0-200 eV, while a preferred ion source voltage range is 0-250 V with an ion energy of 0-120 eV. Note that 0 V ion source is a preferred voltage in some cases, which means no ion source is DC powered (instead, solely relying on RF power) if the magnetron is set at an optimum angle θ. Although the deposited thin film can have less desirable properties as compared with the film deposited with optimum ion energy, the process and vacuum system are simpler.

The operation of magnetron apparatus using rotary magnetron 353 is as follows. Before the film deposition, vacuum chamber 81 is evacuated using vacuum pumps 89. Then, source gases are introduced from gas supply tank 83 into the chamber through mass flow controllers to establish a processing pressure, preferably in the range of 1-10 mTorr. The beam plasma source is excited by one of the following powers: radio frequency (RF), direct current (DC), pulse DC, or a mixture of DC+RF. Magnetic fields of the energized ion source 55 interact with plasma therein to emit ions, which interact with magnetron 303, to sputter off target material atoms from rotating target 303. The offset angle of at least magnetron 353 and the ion source excitation voltage densify the target atoms in a coating layer on the facing upper surface of substrate 57. Furthermore, the coating thickness can be controlled by the processing time. The offset angle of at least magnetron and the ion source excitation voltage advantageously allow sputter coating on a substrate having a processing temperature less than 200° C., and more preferably between room temperature and 150° C., and preferably without additional post-sputtering heating of the coated substrate. In one exemplary configuration, this low temperature processing creates a polycrystalline structure in the coating layer, but avoids the need for expensive and complex liquid-cooling equipment for the substrate holder.

For any of the embodiments discussed hereinabove, the present magnetron apparatus can be used in a batch laboratory process or in a continuously moving production process. In a production setting, the workpiece substrate can be vertically or more preferably horizontally, as is illustrated. Furthermore, the specimen can be rigid or flexible. If a large substrate is used then multiple magnetrons and ion sources can be provided, but each set located in separate and adjacent vacuum chambers.

While various embodiments have been disclosed, it should be appreciated that other variations may be employed. For example, while the preferred ion source construction is described and illustrated, other ion sources, such as a race-track style, Kaufman style, etc. may alternately be employed, and/or the quantity, shapes or arrangement of magnets and/or shunt may be varied, although some of the desired benefits may not be realized. Furthermore, exemplary target and specimen materials have been identified but other materials may be employed. Moreover, different magnetron magnet, cathode and target shapes and positions can be used, however, they may not function as well as the exemplary configurations shown herein. Each of the features may be interchanged and intermixed between any and all of the disclosed embodiments, and any of the claims may be multiply dependent on any of the others. Additional changes and modification are not to be regarded as a departure from the spirit or the scope of the present invention.

The invention claimed is:

1. A magnetron apparatus comprising:
(a) a vacuum chamber including a plasma area located therein;
(b) reactive gas located in the plasma area;
(c) a workpiece substrate located in the vacuum chamber;
(d) a magnetron comprising:
(i) spaced apart magnetron magnets located in the vacuum chamber;
(ii) a sputter target located adjacent to the magnets;
(iii) a primary axis of the magnetron being offset from a nominal plane of the workpiece substrate by 20-70°;
(e) an ion source comprising:
(i) an anode;
(ii) a cathode;
(iii) ion source magnets positioned with the anode; and
(f) the magnetron and the ion source being configured to ionize the reactive gas within the plasma area and sputter material from the sputter target to create a layer on the workpiece substrate.

2. The apparatus of claim 1, wherein the ion source comprises:
magnetic shunts alternating with the ion source magnets which create a magnetic flux in a central open space inside the anode wherein the plasma is created;
the anode being circular;
a frustoconically tapered surface of the cathode surrounding a single aperture through which ions are emitted, the aperture being coaxial with an ion emission centerline;
at least one of: DC or RF power, supplied to the ion source; and
the ion emission centerline of the ion source being offset angled from the nominal plane of the workpiece substrate and being offset angled from the primary axis of the magnetron.

3. The apparatus of claim 1, wherein:
the magnetron is a planar sputtering magnetron with the primary axis of the magnetron being aligned with a central one of the magnetron magnets;
the target material is substantially flat and on a substrate-facing side of the magnetron magnets prior to the sputtering; and
the offset angle of the primary axis of the magnetron is substantially 45° from the nominal surface of the workpiece substrate.

4. The apparatus of claim 1, wherein:
the magnetron is a rotary sputtering magnetron with the primary axis of the magnetron being aligned with a central one of the magnetron magnets;
the sputter target is substantially cylindrical and is configured to rotate around the magnetron magnets; and
the offset angle of the primary axis of the magnetron is substantially 45° from the nominal surface of the workpiece substrate.

5. The apparatus of claim 1, wherein:
an ion source discharge voltage is 0-400 volts with an ion energy of 0-200 eV;
the layer is a transparent and conductive indium tin oxide film;
the reactive gas comprises Ar and O₂; and
an ion emission centerline of the ion source is substantially 90° to the nominal surface of the workpiece substrate.

6. The apparatus of claim 1, wherein:
an ion source discharge voltage is 0-400 volts with an ion energy of 0-200 eV;
the layer is a ZnTe film; and
the reactive gas comprises a N₂/Ar flow ratio of 0.5-1%, which is configured to act with the ion source to enhance N-doping and a≤4.0 Ohm-cm resistivity of the layer.

7. The apparatus of claim 1, wherein:
an ion source discharge voltage is 0-400 volts with an ion energy of 20-200 eV;
the sputter target comprises one of: (a) ZnTe; (b) indium tin oxide; (c) silver; (d) Ta-doped SnO₂; or (e) NbN; and
the workpiece substrate is polymeric.

8. The apparatus of claim 1, wherein the offset angles of the axis and the centerline are 20-70° relative to the substrate, with the axis and the centerline being offset from each other.

9. The apparatus of claim 1, wherein the offset angle of the axis of the magnetron is 45°+/−2° relative to the substrate, with the axis and the centerline being offset from each other, while a holder moves the substrate relative to the ion source and the magnetron magnets, which are stationary, during sputter coating.

10. The apparatus of claim 1, wherein a temperature of the workpiece substrate is <200° C. during the ion emission and sputtering of the sputter target, and the layer has a polycrystalline thin film structure.

11. The apparatus of claim 1, further comprising a holder supporting and moving the workpiece substrate during the ion emission and the sputtering of the sputter target, the holder acting as an anode, the workpiece substrate being between room temperature and 200° C. during the ion emission and the sputtering of the sputter target, and the axis of the magnetron being angled 35-50° relative to the nominal surface of the substrate.

12. A magnetron apparatus comprising:
(a) a vacuum chamber;
(b) processing gas located in the vacuum chamber;
(c) a workpiece holder located in the vacuum chamber, the workpiece holder including a workpiece-facing surface;
(d) a magnetron comprising:
(i) magnetron magnets located in the vacuum chamber;
(ii) a sputter target located adjacent to the magnets;
(iii) an axis of the magnetron extending toward the workpiece holder, with the axis being offset from a nominal plane of the workpiece-facing surface by 35-50°;
(e) an ion source configured to create a plasma from the gas, the ion source comprising:
(i) an anode;
(ii) a cathode;
(iii) ion source magnets; and
(f) a temperature of the workpiece-facing surface is <200° C. during sputtering of the sputter target.

13. The apparatus of claim 12, wherein the ion source comprises:
magnetic shunts alternating with the ion source magnets which create a magnetic flux in a central open space inside the anode;
a frustoconically tapered surface of the cathode surrounding a single aperture through which ions are emitted, the aperture being coaxial with the ion emission centerline; and
DC and RF power being supplied to the ion source.

14. The apparatus of claim 12, wherein:
the magnetron is a planar sputtering magnetron;
the target material is substantially flat and on a substrate-facing side of the magnetron magnets; and
the holder is configured to support and move a polymeric workpiece substrate during the ion emission and the sputtering, the holder acts as an anode, and the workpiece substrate is between room temperature and 200° C. during the ion emission and the sputtering.

15. The apparatus of claim 12, wherein:
the magnetron is a rotary sputtering magnetron;
the sputter target is substantially cylindrical and rotates around the magnetron magnets; and
the holder is configured to support and move a polymeric workpiece substrate during the ion emission and the sputtering, the holder acts as an anode, and the workpiece substrate is between room temperature and 200° C. during the ion emission and the sputtering.

16. The apparatus of claim 12, wherein:
an ion source discharge voltage is 0-400 volts with an ion energy of 0-200 eV; and
a sputtered layer on a workpiece substrate is a transparent and conductive indium tin oxide film.

17. The apparatus of claim 12, wherein:
an ion source discharge voltage is 0-400 volts with an ion energy of 0-200 eV;
a sputtered layer on a workpiece substrate is a ZnTe film; and
the reactive gas comprises a N₂/Ar flow ratio of 0.5-1%, which is configured to act with the ion source to obtain a≤4.0 Ohm-cm resistivity of the layer.

18. The apparatus of claim 12, wherein:
an ion source discharge voltage is 0-400 volts with an ion energy of 20-200 eV; and
a polymeric workpiece substrate is on the workpiece holder, upon which a sputtered layer is formed.

19. The apparatus of claim 12, wherein the offset angle of the axis is 45°+/−2°.

20. A method of using a sputtering magnetron, the method comprising:
(a) orienting a primary axis of a magnetron at 35-50° offset angled from a nominal plane of a workpiece substrate;
(b) supplying direct current and/or radio frequency power to an anode of an ion source, which includes a magnet;
(c) flowing a reactive gas into a vacuum;
(d) ionizing reactive gas within the vacuum to emit an ion beam out of the ion source and create a plasma in the reactive gas;
(e) sputtering target material from the magnetron to create a layer of the target material on the workpiece substrate;
(f) causing a temperature of the workpiece substrate to be <200° C. during the ion emission and the sputtering of the sputter target, while causing the layer to have a polycrystalline thin film structure.

21. The method of claim 20, wherein:
the magnetron is a planar sputtering magnetron with the primary axis of the magnetron being aligned with a central one of multiple spaced apart magnetron magnets;
the target material is substantially flat and on a substrate-facing side of the magnetron magnets prior to the sputtering; and
orienting an ion emission centerline of the ion source at 20-80° offset angled from the nominal plane of the workpiece substrates, and offset angled from the primary axis of the magnetron.

22. The method of claim 20, wherein:
rotating a sputter target cylinder around the magnets of the magnetron with the primary axis of the magnetron being aligned with a central one of multiple spaced apart magnetron magnets; and
orienting an ion emission centerline of the ion source at 20-80° offset angled from the nominal plane of the workpiece substrates, and offset angled from the primary axis of the magnetron.

23. The apparatus of claim 20, further comprising:
creating an ion source discharge voltage of 0-400 volts with an ion energy of 0-200 eV; and
densifying atoms of the target material in the layer on the workpiece substrate during the sputtering;
growing the layer on the workpiece substrate while the workpiece substrate continuously moves;
the layer being a thin film with an average thickness of 10-100 nm; and
the workpiece substrate including a polymeric material.
